(19) United States
(12) Patent Application Publication
(10) Pub. No.: US 2026/0164908 A1
(43) Pub. Date: Jun. 11, 2026

(54) MICRO LED ARRAY AND MICRO LED DISPLAY PANEL

(71) Applicant: JADE BIRD DISPLAY (SHANGHAI) LIMITED, SHANGHAI (CN)

(72) Inventor: Shuang ZHAO, Shanghai (CN)

(21) Appl. No.: 19/178,923

(22) Filed: Apr. 15, 2025

(30) Foreign Application Priority Data
Apr. 16, 2024 (WO) PCT/CN2024/087932

(51) Int. Cl. H10H 29/85; H10H 20/819; H10H 20/824

(52) U.S. Cl. CPC H10H 29/857; H10H 20/819; H10H 20/824

(57) ABSTRACT

A micro LED array includes a first type epitaxial layer; a light emitting layer continuously formed on a top surface of the first type epitaxial layer; a second type epitaxial layer formed on a top surface of the light emitting layer; and a top contact formed on a top of the second type epitaxial layer, the top contact having a circular structure or a spiral structure.

### CROSS-REFERENCE TO RELATED APPLICATIONS

The present disclosure claims the benefits of priority to PCT Application No. PCT/CN 2024/087932, filed on Apr. 16, 2024, which is incorporated herein by reference in its entirety.

### TECHNICAL FIELD

The present disclosure generally relates to micro display technology, and more particularly, to a micro light emitting diode (LED) array and a micro LED display panel.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED display panel is manufactured by integrating an array of thousands or even millions of micro LEDs with an integrated circuitry back panel. Each pixel of the micro LED display panel is formed by one or more micro LEDs. The micro LED display panel can be a mono-color or multi-color panel. In particular, for a multi-color LED panel, each pixel may further include multiple sub-pixels formed by multiple micro LEDs, each of which corresponds to a different color. For example, three micro LEDs respectively corresponding to red, green, and blue colors may be superimposed to form one pixel. The different colors can be mixed to produce a broad array of colors.

Current micro LED technology faces several challenges, for example, to improve an effective illumination area within each pixel when a distance between the adjacent micro LEDs is determined. Moreover, when a single micro LED illumination area is determined, because micro LEDs with different colors occupy their designated zones within a single pixel, further improving an overall resolution of a micro LED display panel can be a difficult task.

Additionally, the light emitted by micro LED dies is generated from spontaneous emission and is thus not directional, which results in a large divergence angle. The large divergence angle can cause various problems in a micro LED display panel. Due to the large divergence angle, on one hand, only a small portion of the light emitted by the micro LEDs can be utilized, which may significantly reduce the efficiency and brightness of a micro LED display system; on the other hand, the light emitted by one micro LED pixel may illuminate its adjacent pixels, which results in light crosstalk between pixels, loss of sharpness, and loss of contrast.

### SUMMARY OF THE DISCLOSURE

Embodiments of the present disclosure provide a micro LED array. The micro LED array includes a first type epitaxial layer; a light emitting layer continuously formed on a top surface of the first type epitaxial layer; a second type epitaxial layer formed on a top surface of the light emitting layer; and a top contact formed on a top of the second type epitaxial layer, the top contact having a circular structure or a spiral structure.

Embodiments of the present disclosure provide a micro LED display panel. The micro LED display panel includes an integrated circuit (IC) backplane comprising: a first dielectric layer formed on the IC backplane; and a top pad array comprising a plurality of top pads formed in the first dielectric layer; and the above described micro LED array bonded with the IC backplane.

Embodiments of the present disclosure provide a micro LED display panel. The micro LED display panel includes an integrated circuit (IC) backplane comprising: a first dielectric layer formed on the IC backplane; and a top pad array comprising a plurality of top pads formed in the first dielectric layer; and the above described micro LED array bonded with the IC backplane; wherein a bottom of one first bottom mesa is electrically bonded with one top pad.

Embodiments of the present disclosure provide a micro LED display panel. The micro LED display panel includes an integrated circuit (IC) backplane comprising: a first dielectric layer formed on the IC backplane; and a top pad array comprising a plurality of top pads formed in the first dielectric layer; and the above described micro LED array bonded with the IC backplane; wherein the top conductive layer is connected with a signal circuit in IC backplane and the signal circuit is connectable with an external signal source.

Embodiments of the present disclosure provide a micro LED display panel. The micro LED display panel includes an integrated circuit (IC) backplane comprising: an integrated circuit (IC) backplane comprising: a first dielectric layer formed on the IC backplane; and a top pad array comprising a plurality of top pads formed in the first dielectric layer; and the above described micro LED array bonded with the IC backplane; wherein one bottom via is electrically bonded with one top pad; and the bottom dielectric layer is bonded with the first dielectric layer.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing a top view of an example micro LED array, according to some embodiments of the present disclosure.

FIG. 2 illustrates a structural diagram showing a sectional view of the example micro LED array along an A-A′ direction shown in FIG. 1, according to some embodiments of the present disclosure.

FIG. 3 illustrates a structural diagram showing the sectional view of a portion B shown in FIG. 2, according to some embodiments of the present disclosure.

FIG. 4A-FIG. 4C illustrate structural diagrams of various example second upper mesas, according to some embodiments of the present disclosure.

FIG. 5A-FIG. 5D illustrate structural diagrams showing top views of various example top contacts, according to some embodiments of the present disclosure.

FIG. 6 illustrates a structural diagram showing a sectional view of another example micro LED array along an A-A′ direction shown in FIG. 1, according to some embodiments of the present disclosure.

FIG. 7 illustrates a structural diagram showing a sectional view of another example micro LED array along an A-A′ direction shown in FIG. 1, according to some embodiments of the present disclosure.

FIG. 8 illustrates a structural diagram showing a sectional view of another exemplary micro LED array along an A-A′ direction shown in FIG. 1, according to some embodiments of the present disclosure.

FIG. 9 illustrates a structural diagram showing a sectional view of another exemplary micro LED array along an A-A′ direction shown in FIG. 1, according to some embodiments of the present disclosure.

FIG. 10 illustrates a structural diagram showing another top view of the example micro LED array panel shown in FIG. 2 with a micro lens, a top conductive layer, and a top dielectric layer removed from the view, according to some embodiments of the present disclosure.

FIG. 11 illustrates a structural diagram showing a top view of an example first type epitaxial layer, according to some embodiments of the present disclosure.

FIG. 12 illustrates a structural diagram showing a top view of an example micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

Embodiments of the present disclosure provide a micro LED array to improve illumination performance.

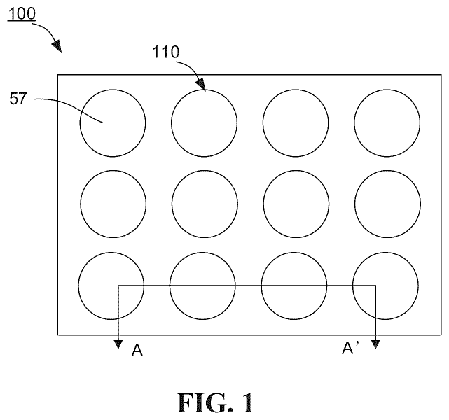

FIG. 1 illustrates a structural diagram showing a top view of an example micro LED array 100, according to some embodiments of the present disclosure. As shown in FIG. 1, micro LED array 100 includes a plurality of micro LED mesas 110 arranged in an array. Each micro LED mesa 110 is covered by a micro lens 57.

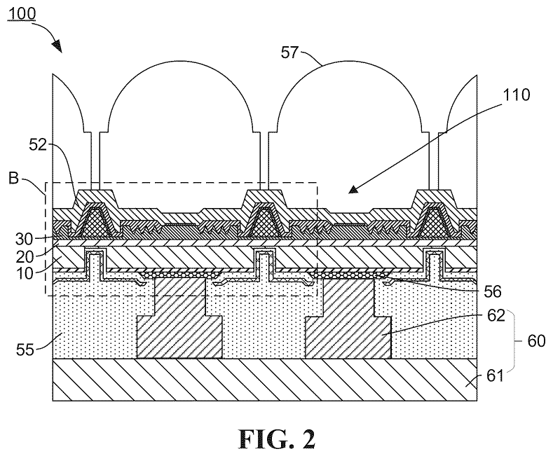

FIG. 2 illustrates a structural diagram showing a sectional view of micro LED array 100 along an A-A′ direction shown in FIG. 1, according to some embodiments of the present disclosure. As shown in FIG. 2, micro LED array 100 includes a first type epitaxial layer 10, a light emitting layer 20, and a second type epitaxial layer 30 formed from bottom to top. Light emitting layer 20 is continuously formed on first type epitaxial layer 10, and second type epitaxial layer 30 is continuously formed on light emitting layer 20. Continuous light emitting layer 20 can improve light emitting performance. First type epitaxial layer 10, light emitting layer 20, and second type epitaxial layer 30 can form a PN junction structure to have light emitting layer 20 emit light. Micro lens 57 is provided above each micro LED mesa 110.

Micro LED array 100 further includes various structures to improve the illumination performance, which will be described below.

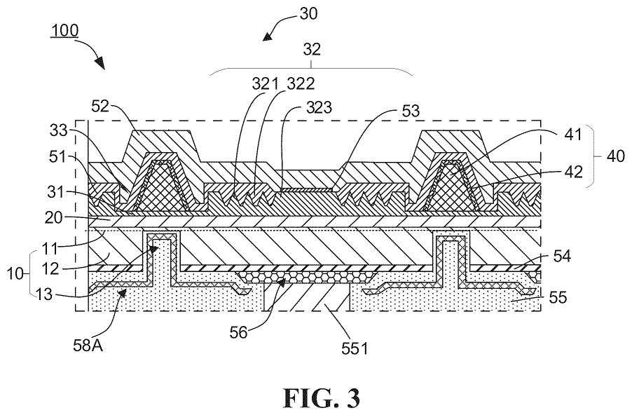

FIG. 3 illustrates a structural diagram showing the sectional view of a portion B of micro LED array 100 shown in FIG. 2, according to some embodiments of the present disclosure. Referring to FIG. 3, first type epitaxial layer 10 includes a first upper continuous layer 11, a first bottom mesa array includes a plurality of first bottom mesas 12, and a first trench 13 provided between adjacent first bottom mesas 12. First bottom mesa 12 is formed at a bottom of first upper continuous layer 11 and each first bottom mesa 12 extends down from first upper continuous layer 11. First upper continuous layer 11 is continuously formed at a bottom of light emitting layer 20. Thus, first trench 13 does not pass through first type epitaxial layer 10 or contact with light emitting layer 20. In some embodiments, a sidewall of first trench 13 is vertical relative to first upper continuous layer 11. In some embodiments, an error angle between the sidewall of first trench 13 and first upper continuous layer 11 is not more than ±5°. That is, an angle formed by the sidewall of first trench 13 and first upper continuous layer 11 is in a range of 85° to 95°. A vertical mesa, e.g., first bottom mesa 12 with a vertical sidewall, can reduce light crosstalk between adjacent micro LEDs.

In some embodiments, a depth to width ratio of first trench 13 is not less than 5. That is, the depth of first trench 13 is at least equal to or greater than 5 times of the width of first trench 13. The depth of first trench 13 is from a top of first trench 13 to a bottom of first type epitaxial layer 10. In some embodiments, the width of first trench 13 is in a range of 100 nm to 3 μm. A high depth to width ratio can reduce light crosstalk between adjacent micro LEDs and, in the meantime, a high light emitting performance can be maintained.

Referring to FIG. 3, second type epitaxial layer 30 includes a second bottom continuous layer 31, a second upper mesa array including a plurality of second upper mesas 32, and a second trench 33 formed between adjacent second upper mesas 32. The second upper mesa array is formed on second bottom continuous layer 31, and each second upper mesa 32 extends up from second bottom continuous layer 31. Second bottom continuous layer 31 is continuously formed on light emitting layer 20. Thus, second trench 33 does not pass through second type epitaxial layer 30 or contact with light emitting layer 20. In some embodiments, a thickness of second bottom continuous layer 31 is in a range of 2 nm to 15 nm, for example, 10 nm. A thickness of first upper continuous layer 11 is in a range of 2 nm to 15 nm, for example, 10 nm. In some embodiments, a width of second trench 33 is greater than the width of the first trench 13. Keeping the thicknesses of first upper continuous layer 11 and second bottom continuous layer 31 as small as possible, laterally emitted light is reduced, therefore, light crosstalk between adjacent micro LEDs can be further reduced.

In some embodiments, second upper mesa 32 includes a plurality of projections 321 and a plurality of sunken portions 322, and a center sub-mesa 323. In some embodiments, each of the plurality of projections 321 has a sharp tip. In some embodiments, the plurality of projections 321 are formed in an array. The array of the plurality of projections 321 is a photonic crystal array, and a cross-sectional shape of a photonic crystal is round or polygonal. In some embodiments, a top surface of center sub-mesa 323 is flat, and the plurality of projections 321 are formed around center sub-mesa 323. In some embodiments, a height of projection 321 is in a range from 10 nm to 5000 nm.

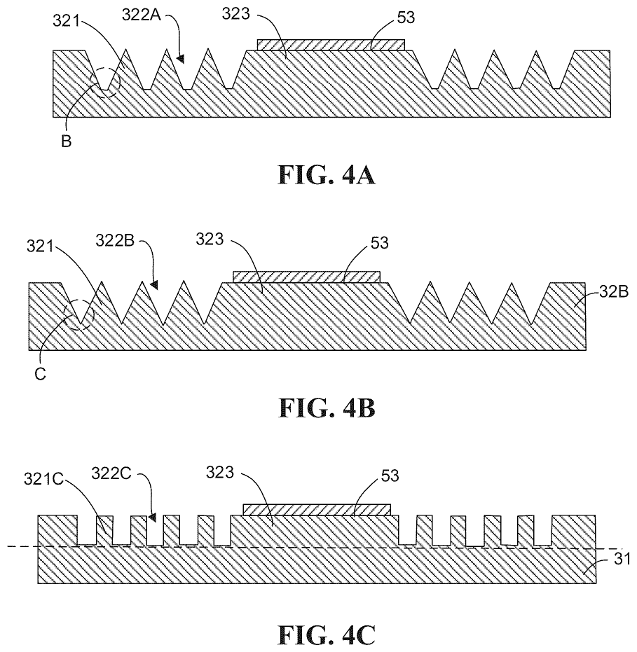

In some embodiments, second upper mesa 32 may include various coarsening structures. FIG. 4A to FIG. 4C illustrate structural diagrams of various example second upper mesa with different structures of projections and sunken portions, according to some embodiments of the present disclosure. Referring to FIG. 4A, a sunken portion 322A may have a flat bottom as shown in portion B. Referring to FIG. 4B, a sunken portion 322B may have a sharp tip at the bottom as shown in portion C. Referring to FIG. 4C, a projection 321C may have a flat top surface, and a sunken portion 322C may have a flat bottom surface. Sidewalls of projection 321C and sunken portion 322C are vertical to second bottom continuous layer 31.

Having a coarsening structure in second upper mesa 32 can improve performance of light with small incident angle emitted by light emitting layer 20.

In some embodiments, a material of first type epitaxial layer 10 is one of AlGaInP, InP, AlInP, GaAs, or GaP. A material of second type epitaxial layer 30 is one of AlGaInP, InP, AlInP, GaAs, or GaP. Light emitting layer 20 is a quantum well layer. Top surfaces of first bottom mesa 12 and second upper mesa 32 are round. A diameter of first bottom mesa 12 is not greater than 50 μm and a diameter of second upper mesa 32 is not greater than the diameter of first bottom mesa 12.

Referring again to FIG. 3, micro LED array 100 further includes an isolation structure 40 formed in second trench 33. Isolation structure 40 is not transparent, for example, isolation structure is black. A material of isolation structure 40 is metal, for example, Cr or Ti, which may absorb most of light. In some embodiments, material of isolation structure 40 is isolation material, for example an omni-directional reflector (ODR) or a distributed Bragg reflector (DBR), which may reflect most lights. The ODR may include a dielectric material and a metal. For example, the dielectric material may include transparent dielectric material such as SiO2, TiO2, Al2O3, MgO, SiNx, SiOxNy, SnO2, ZrO2Y2O3, La2O3, etc. The metal may include Au, Ag, Cu, or Cr, which has high reflectivity for red light. The DBR may include two materials with a high difference in reflectivity alternately layered. For example, the two materials can be selected from SiO2, TiO2, Al2O3, MgO, SiNx, SiOxNy, SnO2, ZrO2Y2O3, or La2O3.

In some embodiments, isolation structure 40 further includes an isolation core 41 and a reflective shell 42 formed on isolation core 41. In some embodiments, a material of isolation core 41 is not metal, and a material of the reflective shell 42 is metal. In some embodiments, the material of isolation core 41 is an isolation material for absorbing lights, and the material of reflective shell 42 is a reflective material for reflecting lights. In some embodiments, the material of isolation core 41 is a reflective material for reflecting lights. In some embodiments, a material of the reflective shell 42 is Au, Ag.

Referring to FIG. 3, micro LED array 100 further includes a top dielectric layer 51 formed on second type epitaxial layer 30 and isolation structure 40. At least part of the surface of each second upper mesa 32 is exposed and not covered by top dielectric layer 51. In some embodiments, the surface of center sub-mesa 323 is exposed and not covered by top dielectric layer 51.

Micro LED array 100 further includes a top conductive layer 52 formed on top dielectric layer 51 and on the exposed surface of second upper mesa 32, for example, on the surface of center sub-mesa 323, which is exposed and not covered by top dielectric layer 51. Micro LED array 100 further includes a top contact 53 formed between the exposed surface of second upper mesa 32 and top conductive layer 52 to provide better ohmic contact for second upper mesa 32. Top contact 53 can be configured to serve as a top ohmic contact of the PN junction structure. Top contact 53 can be transparent, demi-transparent, or not transparent. In some embodiments, top contact 53 is not transparent, and a material of top contact 53 is metal. In some embodiments, an area of top contact 53 is less than half of an area of second upper mesa 32. In some embodiments, top contact 53 is provided at center of second upper mesa 32, for example, on center sub-mesa 323.

In some embodiments, a top surface of top conductive layer 52 is not flat and conforms with a top surface of top dielectric layer 51. In some embodiments, top conductive layer 52 and top dielectric layer 51 are transparent. In some embodiments, a material of top dielectric layer 51 is SiO₂ or Si₃N₄, and a material of top conductive layer 52 is a transparent conductive material.

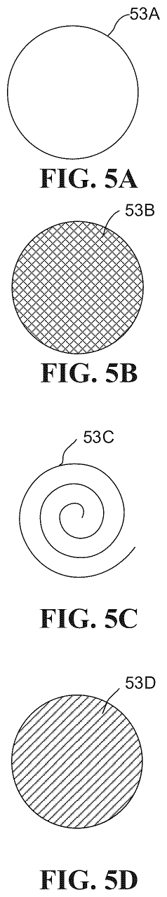

In some embodiments, top contact 53 is transparent and has a circular structure or a spiral structure. In some embodiments, top contact 53 may have metal wires arranged in different patterns. FIG. 5A-FIG. 5D illustrate structural diagrams showing top views of various example top contacts, according to some embodiments of the present disclosure. Referring to FIG. 5A, a top contact 53A has a metal wire circularly arranged. Referring to FIG. 5B, a top contact 53B has a mesh structure configured by metal wires. Referring to FIG. 5C, a top contact 53C has metal wires spirally arranged. Referring to FIG. 5D, a top contact 53D is circular with metal wires arranged at intervals. In some embodiments, a diameter of a metal wire of any of top contacts 53A to 53D is in a range of 1 nm to 50 nm.

With a partially transparent top contact (e.g., top contacts 53A to 53D), a ratio of light with small incident angle can be increased, thereby improving the light emitting performance.

In some embodiments, micro LED array 100 may further include a plurality of N-pads (not shown) provided on top conductive layer 52 and the plurality of N-pads are interconnected to improve the conductivity of top conductive layer 52.

Referring back to FIG. 3, micro LED array 100 further includes a first bottom contact layer 54 formed at a bottom surface of each first bottom mesa 12 to provide better ohmic contact for first bottom mesa 12. First bottom contact layer 54 can be configured to serve as a bottom ohmic contact of the PN junction structure.

Micro LED array 100 further includes a bottom dielectric layer 55 and a bottom via array including a plurality of bottom vias 552 formed at the bottom of first bottom contact layer 54. Bottom dielectric layer 55 is formed at a bottom of first bottom contact layer 54 and filled in first trench 13. One bottom via 552 corresponds to one first bottom mesa 12. In some embodiments, bottom vias 552 are formed at bottoms of first bottom mesas 12 of the first bottom mesa array and in bottom dielectric layer 55. In some embodiments, bottom via 552 is a metal bottom via.

In some embodiments, bottom dielectric layer 55 includes a plurality of metal via 551. Each metal via 551 corresponds to a bottom of each first bottom mesa 12, respectively. In some embodiments, metal via 551 is configured as a metal pad of an integrated circuit backplane to connect the IC backplane with bottom via 552.

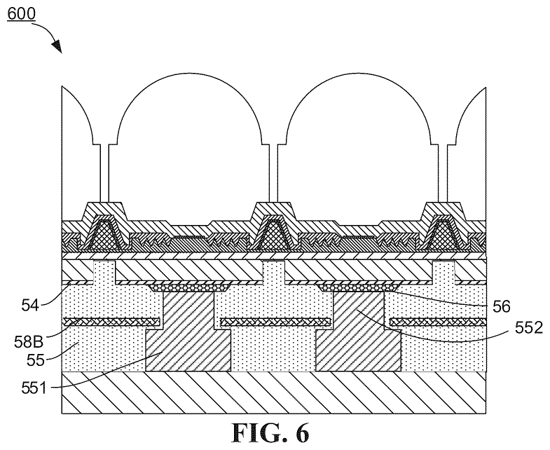

In some embodiments, referring to FIG. 6, micro LED array 100 further includes a second bottom contact layer 56. Second bottom contact layer 56 is formed at a bottom of first bottom contact layer 54. Second bottom contact layer 56 can provide ohmic contact and is further configured to be reflective. A material of second bottom contact layer 56 is a reflective material. In some embodiments, first bottom contact layer 54 covers a whole bottom surface of the first bottom mesa 12, and an area of second bottom contact layer 56 is smaller than an area of first bottom contact layer 54. In some embodiments, the area of second bottom contact layer 56 corresponding to each first bottom mesa 12 is not less than an area of a top surface of each bottom via 552. Second bottom contact layer 56 is formed between first bottom contact layer 54 and bottom via 552. In some embodiments, a material of first bottom contact layer 54 is transparent conductive material, a material of second bottom contact layer 56 is metal, and a material of bottom dielectric layer 55 is SiO₂ or Si₃N₄.

In some embodiments, a bottom of the bottom via 552 extends down from a bottom of first bottom contact layer 54.

Still referring to FIG. 3, micro LED array 100 further includes a bottom reflective layer 58A provided in bottom dielectric layer 55 and under first type epitaxial layer 10. Bottom reflective layer 58A is used to reflect upward light emitted by light emitting layer 20.

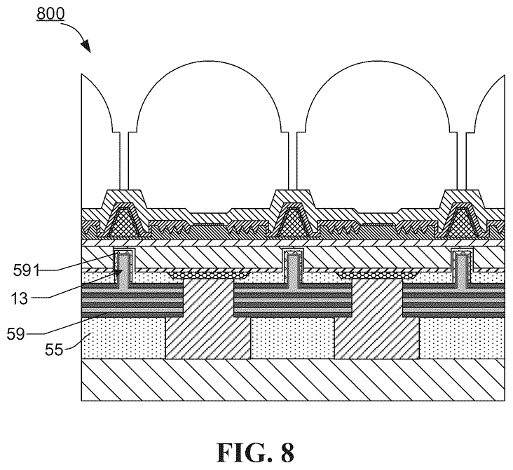

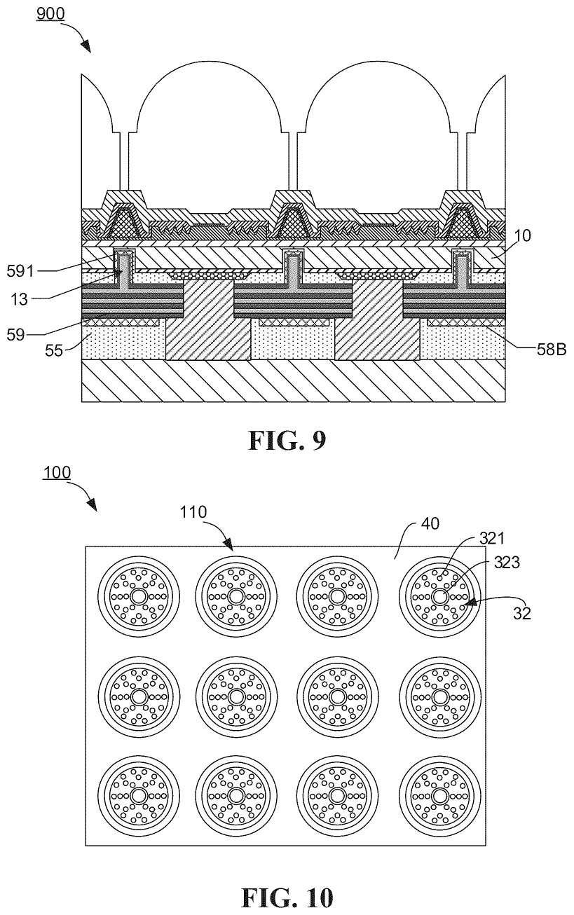

In this example, bottom reflective layer 58A is formed under each first bottom mesa 12, filled in each first trench 13, and around each bottom via 552. In some embodiments, bottom reflective layer 58A in each first trench 13 is a reflective trench, and bottom dielectric layer 55 is also filled in the reflective trench. In some embodiments, an end of bottom reflective layer 58A is not connected with bottom via 552. In some embodiments, each end of bottom reflective layer 58A near bottom via 552 is lower than the remainder of bottom reflective layer 58A. In some embodiments, a thickness of bottom reflective layer 58A is in a range of 5 nm to 2000 nm, and a material of bottom reflective layer 58Ais metal, for example, Au, Cu, Ag, Pt, Al, Ti, or Cr. In some embodiments, a distance between a bottom of first bottom mesa 12 and a top of bottom reflective layer 58A under first bottom mesa 12 is in a range of 5 nm to 1000 nm. In some embodiments, bottom reflective layer 58A is a single layer. In some embodiments, bottom reflective layer 58A has a multi-layer structure, for example, a distributed Bragg reflection (DBR) layer (more details will be described in FIG. 8 and FIG. 9). In some embodiments, bottom reflective layer 58A may be provided at a different position and with a different structure.

FIG. 6 illustrates a structural diagram showing a sectional view of a micro LED array 600 along an A-A′ direction shown in FIG. 1, according to some embodiments of the present disclosure. As shown in FIG. 6, a bottom reflective layer 58B of micro LED array 600 is provided under first bottom contact layer 54 and in bottom dielectric layer 55 around metal vias 551. In some embodiments, a top of bottom reflective layer 58B is lower than a bottom of bottom via 552. In some embodiments, an end of bottom reflective layer 58B is not connected with metal via 551.

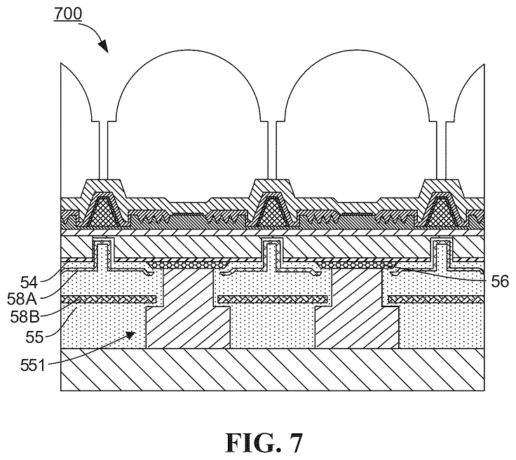

FIG. 7 illustrates a structural diagram showing a sectional view of a micro LED array700 along an A-A′ direction shown in FIG. 1, according to some embodiments of the present disclosure. As shown in FIG. 7, micro LED array 700 includes a bottom reflective layer 58A and a bottom reflective layer 58B. Description of bottom reflective layer 58A can refer to bottom reflective layer 58A of micro LED array 100 show in FIG. 3, and description of bottom reflective layer 58B can refer to bottom reflective layer 58B of micro LED array 600 show in FIG. 6, which will not repeat here.

Details about other structures of micro LED array 600 and micro LED array 700 are those described above with reference to FIG. 2 and FIG. 3, which will not be repeated herein.

FIG. 8 illustrates a structural diagram showing a sectional view of another exemplary micro LED array 800 along an A-A′ direction shown in FIG. 1, according to some embodiments of the present disclosure. As shown in FIG. 8, in this example, bottom reflective layer 58A is a distributed Bragg reflection (DBR) layer 59 provided in bottom dielectric layer 55 and under first type epitaxial layer 10. In some embodiments, DBR layer 59 is further filled in trench 13 and a protruding portion is formed in trench 13. Micro LED array 800 further includes a reflective cap 591 covering the protruding portion to prevent light crosstalk. In some embodiments, a material of reflective cap 591 is metal. Details about other structures of micro LED array 800 are those described above with reference to FIG. 2 and FIG. 3, which will not be repeated herein.

FIG. 9 illustrates a structural diagram showing a sectional view of another exemplary micro LED array 900 along an A-A′ direction shown in FIG. 1, according to some embodiments of the present disclosure. As shown in FIG. 9, micro LED array 900 further includes a bottom reflective layer 58B provided at a bottom surface of DBR layer 59 and in bottom dielectric layer 55. In some embodiments, an end of bottom reflective layer 58B is not connected with metal via 551.

Details about other structures of micro LED array 900 are those described above with reference to FIG. 8, which will not be repeated herein.

Referring to FIG. 2, micro LED array 100 further includes a transparent micro lens array includes a plurality of micro lenses 57 formed on a top surface of top conductive layer 52.

FIG. 10illustrates a structural diagram showing another top view of the example micro LED array panel shown in FIG. 2 with micro lens 57, top conductive layer 52, and top dielectric layer 51 removed from the view, according to some embodiments of the present disclosure. Referring to FIG. 10, center sub-mesa 323 of second upper mesa 32 is provided at the center of micro LED mesa110, projections 321 of second upper mesa 32 are arranged in an array around center sub-mesa 323. Isolation structure 40 is provided between adjacent micro LED mesas110.

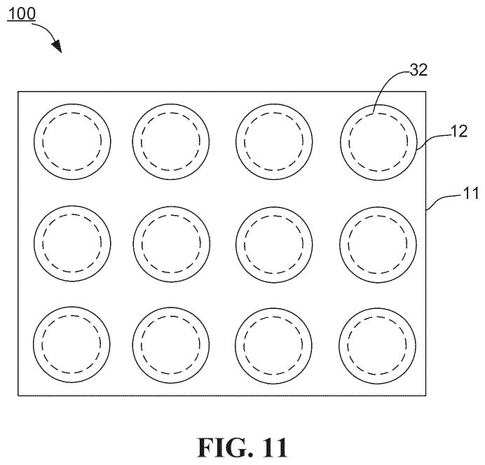

FIG. 11 illustrates a structural diagram showing a top view of first type epitaxial layer 10, according to some embodiments of the present disclosure. Referring to FIG. 11, a diameter of second upper mesa 32 is not greater than the diameter of first bottom mesa 12.

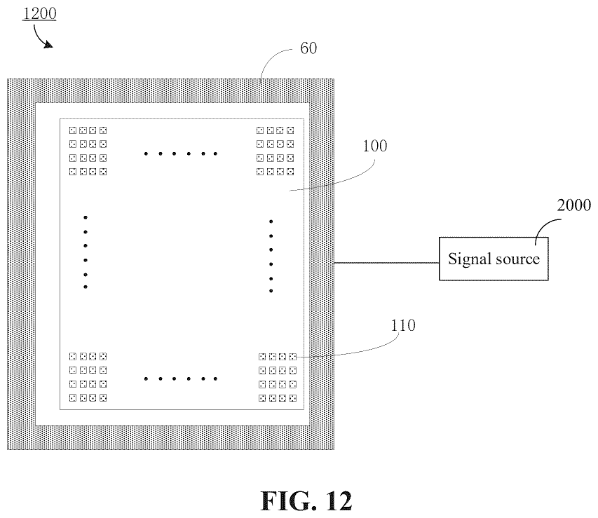

Embodiments of present disclosure further provide a micro LED display panel. FIG. 12 illustrates a structural diagram showing a top view of a micro LED display panel 1200, according to some embodiments of the present disclosure.

As shown in FIG. 12, micro LED display panel 1200 includes an integrated circuit (IC) backplane 60 and a micro LED array 100 provided according to embodiments of the present disclosure. Referring back to FIG. 2, IC backplane 60 includes a first dielectric layer 61 and a top pad array including a plurality of top pads 62 provided on first dielectric layer 61. Micro LED array 100 is bonded with IC backplane 60. A bottom of each first bottom mesa 12 is electrically bonded with one of top pads 62, respectively. In some embodiments, bottom dielectric layer 55 is bonded with first dielectric layer 61. In some embodiments, top pad 62 is received in metal via 551 to connect with bottom via 552.

In some embodiments, top conductive layer 52 is connectable with an external signal source 2000. More particularly, top conductive layer 52 is connectable with a signal circuit in IC backplane 60 and the signal circuit is connected with the external signal source 2000. In some embodiments, micro LED display panel 1200 is used in a micro image sensor device.

Each micro LED herein (e.g., micro LED mesa 110) has a very small volume. The micro LED can be applied in a micro LED display panel. The light emitting area of the micro LED display panel, e.g., micro LED display panel 1200, is very small, such as 1 mm×1 mm, 3 mm×5 mm, etc. In some embodiments, the light emitting area is the area of the micro LED array in the micro LED display panel. The micro LED display panel includes one or more micro LED mesas110 that form a pixel array in which the micro LEDs are pixels, such as a 1600×1200, 680×480, or 1920×1080-pixel array. The diameter of each micro LED is in the range of about 200 nm to 2 μm. An IC backplane, e.g., IC backplane 60, is formed at the back surface of micro LED array 100 and is electrically connected with micro LED array 100. IC backplane 60 acquires signals such as image data from outside via signal lines to control corresponding micro LED mesas 110 to emit light or not.

Different types of micro LED panels can be provided. For example, the resolution of a display panel can range typically from 8×8 to 3840×2160. Common display resolutions include QVGA (Quarter Video Graphics Array) with 320×240 resolution and an aspect ratio of 4:3, XGA (Extended Graphics Array) with 1024×768 resolution and an aspect ratio of 4:3, D (Definition) with 1280×720 resolution and an aspect ratio of 16:9, FHD (Full High Definition) with 1920×1080 resolution and an aspect ratio of 16:9, UHD (Ultra High Definition) with 3840×2160 resolution and an aspect ratio of 16:9, and 4K with 4096×2160 resolution. There can also be a wide variety of pixel sizes, ranging from sub-micron and below to 10 mm and above. The size of the overall display region can also vary widely, ranging from diagonals as small as tens of microns or less up to hundreds of inches or more.

The embodiments may further be described using the following clauses:
1. A micro LED array, comprising:
   a first type epitaxial layer;
   a light emitting layer continuously formed on a top surface of the first type epitaxial layer;
   a second type epitaxial layer formed on a top surface of the light emitting layer; and
   a top contact formed on a top of the second type epitaxial layer, the top contact having a circular structure or a spiral structure.
2. The micro LED array according to claim 1, wherein the top contact is transparent.
3. The micro LED array according to clause 2, wherein the top contact includes metal wires arranged in a pattern.
4. The micro LED array according to clause 1, wherein the second type epitaxial layer comprises:
   a bottom continuous layer formed on the light emitting layer;
   an upper mesa array comprising a plurality of upper mesas extending up from the bottom continuous layer, wherein the upper mesa comprises a plurality of projections and a plurality of sunken portions; and
   a trench formed between adjacent ones of the upper mesas.
5. The micro LED array according to clause 4,
   wherein each of the plurality of projections comprises a sharp tip.
6. The micro LED array according to clause 4, wherein the plurality of projections are formed in an array.
7. The micro LED array according to clause 6, wherein the array of the plurality of projections is a photonic crystal array, and a cross-sectional shape of a photonic crystal is round or polygonal.
8. The micro LED array according to clause 4, wherein the upper mesa further comprises a center sub-mesa, and a top surface of the center sub-mesa is flat and the plurality of projections are formed around the center sub-mesa.
9. The micro LED array according to clause 4, wherein a height of the projections is in a range of 10 nm to 5000 nm.
10. The micro LED array according to clause 4, wherein the bottom continuous layer is a second bottom continuous layer, the upper mesa is a second upper mesa, the upper mesa array is a second upper mesa array, and the trench is a second trench; wherein the first type epitaxial layer comprising:
   a first upper continuous layer;
   a first bottom mesa array comprising a plurality of first bottom mesas, wherein the first bottom mesa array is formed at a bottom of the first upper continuous layer and extends down from the first upper continuous layer; and
   a first trench formed between adjacent first bottom mesas.
11. The micro LED array according to clause 10, wherein a sidewall of the first trench is vertical to the first upper continuous layer.
12. The micro LED array according to clause 11, wherein an error angle between the sidewall of the first trench and the first upper continuous layer is not more than ±5°.
13. The micro LED array according to clause 11, wherein a depth to width ratio of the first trench is not less than 5.
14. The micro LED array according to clause 13, wherein a width of the first trench is from 100 nm to 3 μm.
15. The micro LED array according to clause 10, wherein a thickness of the second bottom continuous layer is from 2 nm to 15 nm, and a thickness of the first upper continuous layer is from 2 nm to 15 nm.
16. The micro LED array according to clause 10, wherein a width of the second trench is greater than a width of the first trench.
17. The micro LED array according to clause 10, further comprising an isolation structure formed in the second trench.
18. The micro LED array according to clause 17, wherein the isolation structure is not transparent, and a material of the isolation structure is metal or isolation material.
19. The micro LED array according to clause 17, wherein the isolation structure comprises an isolation core and a reflective shell formed on the isolation core.
20. The micro LED array according to clause 19, wherein a material of the isolation core is not metal, and a material of the reflective shell is metal.
21. The micro LED array according to clause 17, further comprising a top dielectric layer formed on the second type epitaxial layer and the isolation structure, and at least part surface of each second upper mesa is exposed from the top dielectric layer.
22. The micro LED array according to clause 21, further comprising a top conductive layer formed on the top dielectric layer and on the exposed surface of the second upper mesa.
23. The micro LED array according to clause 22, wherein the top contact is formed between the exposed surface of the second upper mesa and the top conductive layer.
24. The micro LED array according to clause 23, wherein an area of the top contact is less than half of an area of the second upper mesa.
25. The micro LED array according to clause 22, wherein a top surface of the top conductive layer is not flat, and conforms with a top surface of the top dielectric layer.
26. The micro LED array according to clause 10, further comprising a first bottom contact layer formed at a bottom surface of the first bottom mesa.
27. The micro LED array according to clause 26, further comprising:
   a bottom dielectric layer formed at a bottom of the first bottom contact layer and filled in the first trench; and
   a bottom via array comprising a plurality of bottom vias formed at the bottom of the first bottom contact layer, wherein one bottom via corresponds to one first bottom mesa.
28. The micro LED array according to clause 27, further comprising a bottom reflective layer formed under the first bottom mesa, filled in the first trench, and around the bottom via, wherein the bottom reflective layer is provided in the bottom dielectric layer.
29. The micro LED array according to clause 28, wherein the bottom reflective layer is a reflective trench in the first trench, and the bottom dielectric layer is filled in the reflective trench.
30. The micro LED array according to clause 27, further comprising a bottom reflective layer formed under the first bottom mesa and around the bottom via, wherein the bottom reflective layer is provided in the bottom dielectric layer.
31. The micro LED array according to clause 27, further comprising a second bottom contact layer formed at a bottom of the first bottom contact layer, wherein a material of second bottom contact layer is a reflective material.
32. The micro LED array according to clause 31, wherein an area of the second bottom contact layer corresponding to each first bottom mesa is not less than an area of a top surface of each bottom via.
33. The micro LED array according to clause 31, wherein a material of the first bottom contact layer is transparent conductive material, a material of the second bottom contact layer is metal, and a material of the bottom dielectric layer is SiO₂ or Si₃N₄.

34. The micro LED array according to clause 27, wherein a bottom of the bottom via extends down from a bottom of the first bottom contact layer.
35. The micro LED array according to clause 22, further comprising a transparent micro lens array comprising a plurality of micro lenses formed on a top surface of the top conductive layer.
36. The micro LED array according to clause 22, wherein the top conductive layer and the top dielectric layer are transparent.
37. The micro LED array according to clause 22, wherein a material of the top dielectric layer is SiO₂ or Si₃N₄, and a material of the top conductive layer is a transparent conductive material.
38. The micro LED array according to clause 10, wherein a material of the first type epitaxial layer is one of AlGaInP, InP, AlInP, GaAs, or GaP; a material of the second type epitaxial layer is one of AlGaInP, InP, AlInP, GaAs, or GaP; the light emitting layer is a quantum well layer; a diameter of the first bottom mesa is not greater than 50 μm; and a diameter of the second upper mesa is not greater than the diameter of the first bottom mesa.
39. A micro LED display panel, comprising,
   an integrated circuit (IC) backplane comprising:
      a first dielectric layer formed on the IC backplane; and
      a top pad array comprising a plurality of top pads formed in the first dielectric layer; and
   a micro LED array according to any one of clauses 1 to 38 bonded with the IC backplane.
40. A micro LED display panel, comprising:
   an integrated circuit (IC) backplane comprising:
      a first dielectric layer formed on the IC backplane; and
      a top pad array comprising a plurality of top pads formed in the first dielectric layer; and
   a micro LED array according to any one of clauses 10 to 37 bonded with the IC backplane; wherein a bottom of one first bottom mesa is electrically bonded with one top pad.
41. A micro LED display panel, comprising,
   an integrated circuit (IC) backplane comprising:
      a first dielectric layer formed on the IC backplane; and
      a top pad array comprising a plurality of top pads formed in the first dielectric layer; and
   a micro LED array according to any one of clauses 22 to 24 and 35 to 37 bonded with the IC backplane; wherein the top conductive layer is connected with a signal circuit in IC backplane and the signal circuit is connectable with an external signal source.
42. The micro LED display panel according to clause 41, wherein the micro LED display panel is used in a micro image sensor device.
43. A micro LED display panel, comprising:
   an integrated circuit (IC) backplane comprising:
      a first dielectric layer formed on the IC backplane; and
      a top pad array comprising a plurality of top pads formed in the first dielectric layer; and
   a micro LED array according to any one of clauses 26 to 34, bonded with the IC backplane; wherein one bottom via is electrically bonded with one top pad; and the bottom dielectric layer is bonded with the first dielectric layer.

It should be noted that the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED array, comprising:
a first type epitaxial layer;
a light emitting layer continuously formed on a top surface of the first type epitaxial layer;
a second type epitaxial layer formed on a top surface of the light emitting layer; and
a top contact formed on a top of the second type epitaxial layer, the top contact having a circular structure or a spiral structure.

2. The micro LED array according to claim 1, wherein the top contact is transparent.

3. The micro LED array according to claim 2, wherein the top contact includes metal wires arranged in a pattern.

4. The micro LED array according to claim 1, wherein the second type epitaxial layer comprises:
a bottom continuous layer formed on the light emitting layer;
an upper mesa array comprising a plurality of upper mesas extending up from the bottom continuous layer, wherein the upper mesa comprises a plurality of projections and a plurality of sunken portions; and
a trench formed between adjacent ones of the upper mesas.

5. The micro LED array according to claim 4,
wherein each of the plurality of projections comprises a sharp tip.

6. The micro LED array according to claim 4, wherein the plurality of projections are formed in an array.

7. The micro LED array according to claim 6, wherein the array of the plurality of projections is a photonic crystal array, and a cross-sectional shape of a photonic crystal is round or polygonal.

8. The micro LED array according to claim 4, wherein the upper mesa further comprises a center sub-mesa, and a top surface of the center sub-mesa is flat and the plurality of projections are formed around the center sub-mesa.

9. The micro LED array according to claim 4, wherein a height of the projections is in a range of 10 nm to 5000 nm.

10. The micro LED array according to claim 4, wherein the bottom continuous layer is a second bottom continuous layer, the upper mesa is a second upper mesa, the upper mesa array is a second upper mesa array, and the trench is a second trench; wherein the first type epitaxial layer comprising:
a first upper continuous layer;
a first bottom mesa array comprising a plurality of first bottom mesas, wherein the first bottom mesa array is formed at a bottom of the first upper continuous layer and extends down from the first upper continuous layer; and
a first trench formed between adjacent first bottom mesas.

11. The micro LED array according to claim 10, wherein a sidewall of the first trench is vertical to the first upper continuous layer.

12. The micro LED array according to claim 11, wherein an error angle between the sidewall of the first trench and the first upper continuous layer is not more than ±5°.

13. The micro LED array according to claim 11, wherein a depth to width ratio of the first trench is not less than 5.

14. The micro LED array according to claim 13, wherein a width of the first trench is from 100 nm to 3 μm.

15. The micro LED array according to claim 10, wherein a thickness of the second bottom continuous layer is from 2 nm to 15 nm, and a thickness of the first upper continuous layer is from 2 nm to 15 nm.

16. The micro LED array according to claim 10, wherein a width of the second trench is greater than a width of the first trench.

17. The micro LED array according to claim 10, further comprising an isolation structure formed in the second trench.

18. The micro LED array according to claim 17, wherein the isolation structure is not transparent, and a material of the isolation structure is metal or isolation material.

19. The micro LED array according to claim 17, wherein the isolation structure comprises an isolation core and a reflective shell formed on the isolation core.

20. The micro LED array according to claim 19, wherein a material of the isolation core is not metal, and a material of the reflective shell is metal.

21. The micro LED array according to claim 17, further comprising a top dielectric layer formed on the second type epitaxial layer and the isolation structure, and at least part surface of each second upper mesa is exposed from the top dielectric layer.

22. The micro LED array according to claim 21, further comprising a top conductive layer formed on the top dielectric layer and on the exposed surface of the second upper mesa.

23. The micro LED array according to claim 22, wherein the top contact is formed between the exposed surface of the second upper mesa and the top conductive layer.

24. The micro LED array according to claim 23, wherein an area of the top contact is less than half of an area of the second upper mesa.

25. The micro LED array according to claim 22, wherein a top surface of the top conductive layer is not flat, and conforms with a top surface of the top dielectric layer.

26. The micro LED array according to claim 10, further comprising a first bottom contact layer formed at a bottom surface of the first bottom mesa.

27. The micro LED array according to claim 26, further comprising:
a bottom dielectric layer formed at a bottom of the first bottom contact layer and filled in the first trench; and
a bottom via array comprising a plurality of bottom vias formed at the bottom of the first bottom contact layer, wherein one bottom via corresponds to one first bottom mesa.

28. The micro LED array according to claim 27, further comprising a bottom reflective layer formed under the first bottom mesa, filled in the first trench, and around the bottom via, wherein the bottom reflective layer is provided in the bottom dielectric layer.

29. The micro LED array according to claim 28, wherein the bottom reflective layer is a reflective trench in the first trench, and the bottom dielectric layer is filled in the reflective trench.

30. The micro LED array according to claim 27, further comprising a bottom reflective layer formed under the first bottom mesa and around the bottom via, wherein the bottom reflective layer is provided in the bottom dielectric layer.

31. The micro LED array according to claim 27, further comprising a second bottom contact layer formed at a bottom of the first bottom contact layer, wherein a material of second bottom contact layer is a reflective material.

32. The micro LED array according to claim 31, wherein an area of the second bottom contact layer corresponding to each first bottom mesa is not less than an area of a top surface of each bottom via.

33. The micro LED array according to claim 31, wherein a material of the first bottom contact layer is transparent conductive material, a material of the second bottom contact layer is metal, and a material of the bottom dielectric layer is SiO₂ or Si₃N₄.

34. The micro LED array according to claim 27, wherein a bottom of the bottom via extends down from a bottom of the first bottom contact layer.

35. The micro LED array according to claim 22, further comprising a transparent micro lens array comprising a plurality of micro lenses formed on a top surface of the top conductive layer.

36. The micro LED array according to claim 22, wherein the top conductive layer and the top dielectric layer are transparent.

37. The micro LED array according to claim 22, wherein a material of the top dielectric layer is SiO₂ or Si₃N₄, and a material of the top conductive layer is a transparent conductive material.

38. The micro LED array according to claim 10, wherein a material of the first type epitaxial layer is one of AlGaInP, InP, AlInP, GaAs, or GaP; a material of the second type epitaxial layer is one of AlGaInP, InP, AlInP, GaAs, or GaP; the light emitting layer is a quantum well layer; a diameter of the first bottom mesa is not greater than 50 μm; and a diameter of the second upper mesa is not greater than the diameter of the first bottom mesa.

39. A micro LED display panel, comprising,
an integrated circuit (IC) backplane comprising:
a first dielectric layer formed on the IC backplane; and
a top pad array comprising a plurality of top pads formed in the first dielectric layer; and
a micro LED array bonded with the IC backplane, wherein the micro LED array comprises:
a first type epitaxial layer;
a light emitting layer continuously formed on a top surface of the first type epitaxial layer;
a second type epitaxial layer formed on a top surface of the light emitting layer; and
a top contact formed on a top of the second type epitaxial layer, the top contact having a circular structure or a spiral structure.
